(19) United States
(12) Patent Application Publication
(10) Pub. No.: US 2017/0273169 A1
(43) Pub. Date: Sep. 21, 2017

(54) HEAT SINK WITH A LOAD SPREADING BAR

(71) Applicant: HEWLETT PACKARD ENTERPRISE DEVELOPMENT LP, Houston, TX (US)

(72) Inventors: Kevin D CONN, Montgomery, TX (US); Harvey Edward WHITE, Houston, TX (US); Gordon Scott REESE, SR., Houston, TX (US)

(21) Appl. No.: 15/500,056

(22) PCT Filed: Sep. 24, 2014
(86) PCT No.: PCT/US2014/057165

§ 371 Date: Jan. 28, 2017

(51) Int. Cl. H05K 1/02; G06F 1/20

(52) U.S. Cl. CPC H05K 1/0203; G06F 1/206

(57) ABSTRACT

Example implementations relate to a heat sink. For example, an implementation includes a heat sink including a main region to interface with an electronic device mounted to a printed circuit board. The heat sink also includes a load spreading bar coupled to the main region. The load spreading bar includes a first attachment region including a first attachment feature and a second attachment feature. The first attachment feature is to interface with an upper side of the printed circuit board and the second attachment feature is to interface with a lower side of the printed circuit board. The load spreading bar also includes a second attachment region to interface with the printed circuit board.

BACKGROUND

A heat sink is a passive heat exchanger used to reduce an operating temperature of an electronic device, such as a processor and a memory module, by dissipating heat generated by the electronic device into the surrounding environment. A heat sink may be made from material with a high thermal conductivity, such as aluminum alloys.

### BRIEF DESCRIPTION OF THE DRAWINGS

Some examples of the present application are described with respect to the following figures:

FIG. 1 is a perspective view of heat sink with a load spreading bar, according to an example;

FIG. 2 is a perspective view of a heat sink with load spreading bar, according to an example;

FIG. 3 is a top view of a heat sink with a load spreading bar mounted to a printed circuit board, according to an example;

FIG. 4 is a side view of a heat sink with a load spreading bar, according to an example; and

FIG. 5 is a respective view of an attachment region of a load spreading bar of a heat sink, according to an example.

### DETAILED DESCRIPTION

As described above, a heat sink is a passive heat exchanger used to reduce an operating temperature of an electronic device by dissipating heat generated by the electronic device into the surrounding environment. A heat sink may interface with an electronic device via physical contact to transfer the heat away from the electronic device. However, when a heat sink is mounted to a printed circuit board where the electronic device is also mounted to, the weight of the heat sink may increase a likelihood of structural flexing experienced by the printed circuit board. Thus, a likelihood of damage to the printed circuit board due to structural flexing may be increased.

Examples described herein provide a heat sink with a load spreading bar. For example, a heat sink may include a main region and a load spreading bar coupled to the main region. The main region may interface with an electronic device mounted to a printed circuit board. The load spreading bar may include a first attachment region including a first attachment feature and a second attachment feature. The first attachment feature may interface with the upper side and the second attachment feature may interface with the lower side. In this manner, examples described herein may decrease a likelihood of damage to the printed circuit board due to structural flexing may be reduced.

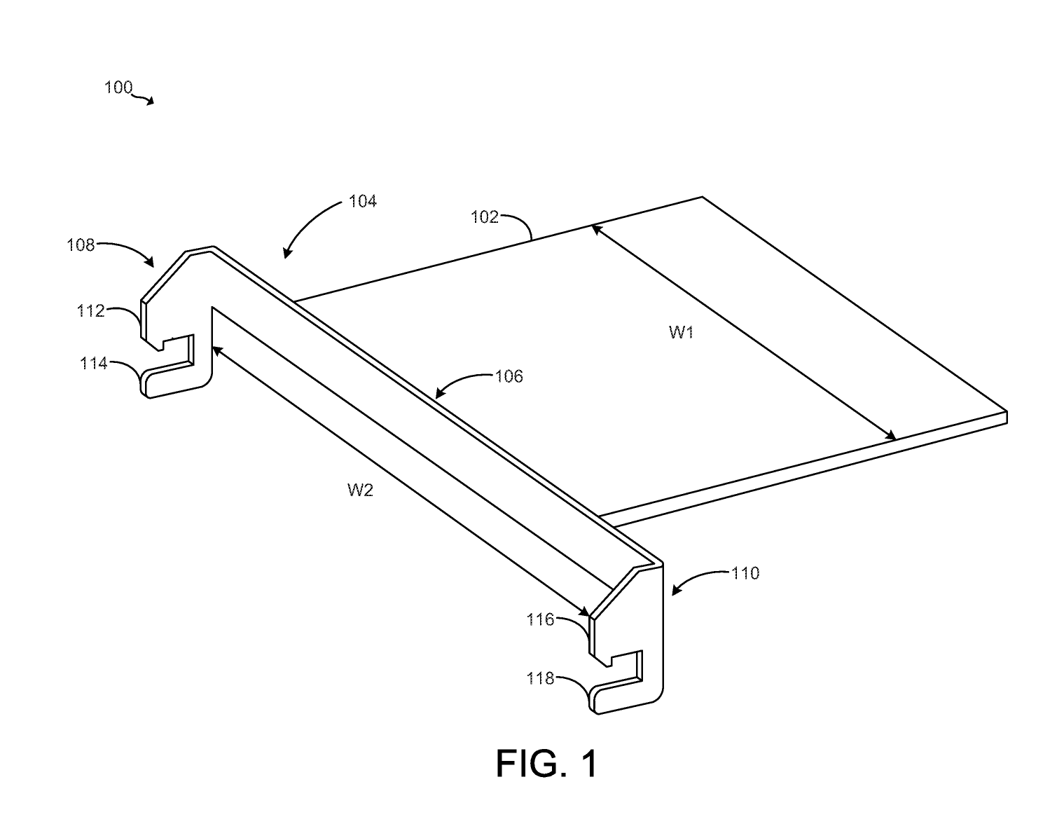

Referring now to the figures, FIG. 1 is a perspective view of a heat sink 100 with a load spreading bar, according to an example. Heat sink 100 may be a heat exchanger that dissipates heat generated by an electronic device into the surrounding environment. In some examples, heat sink 100 may be made from material having a high thermal conductivity, such as aluminum alloys or copper.

Heat sink 100 may include a main region 102 and a load spreading bar 104 coupled to main region 102. Main region 102 may be a region or a portion of heat sink 100 that interfaces with an electronic device, such as a processor or a memory module, via physical contact.

In some examples, load spreading bar 104 may be formed integrally with main region 102 so that load spreading bar 104 is coupled to main region 102. In some examples, load spreading bar 104 may be formed as a single structure and load spreading bar 104 may be coupled to main region 102 via soldering or another coupling mechanism.

Load spreading bar 104 may be a structure that distributes up and down motions experienced a printed circuit board, such as during shipping, to edges of the printed circuit board. Load spreading bar 104 may include a body region 106, a first attachment region 108, and a second attachment region 110. In some examples, body region 106 may be substantially straight. As used herein, substantially straight may mean that body region 106 may have a tolerance of +/−0.25 millimeter. In some examples, body region 106 may be curved.

First attachment region 108 may include a first attachment feature 112 and a second attachment feature 114. Attachment features 112-114 may be any structure to engage a printed circuit board so that heat sink 100 may be mounted or coupled to the printed circuit board. In some examples, first attachment feature 112 may be a first tab that extends from load spreading bar 104. Second attachment feature 114 may be a second tab that extends from first attachment feature 112.

Second attachment region 110 may include a third attachment feature 116 and a fourth attachment feature 118. In some examples, third attachment feature 116 may be similar to first attachment feature 112. Fourth attachment feature 118 may be similar to second attachment feature 114. In some examples, third attachment feature 116 may be a third tab that extends from load spreading bar 104. Fourth attachment feature 118 may be a fourth tab that extends from third attachment feature 116. In some examples, main region 102 may have a width W1. The distance, W2, between first attachment region 108 and second attachment region 110 may be greater than the width W1.

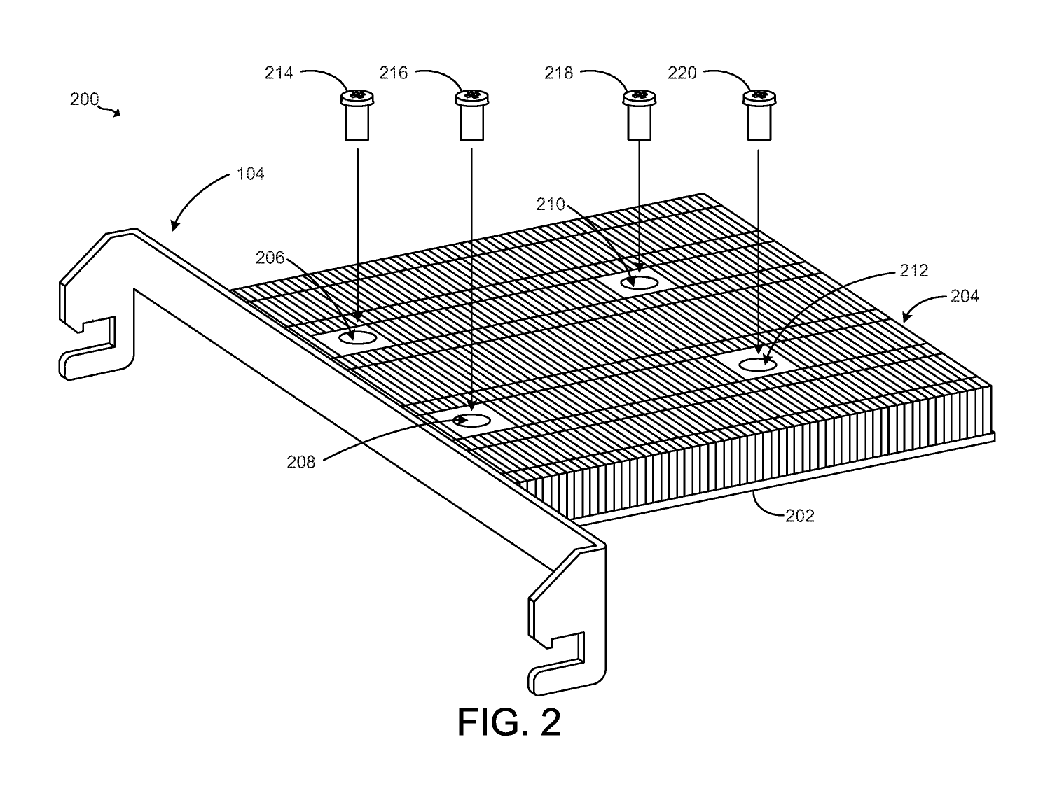

During operation, heat sink 100 may interface with an electronic device, such as a processor or a memory module, via physical contact. Heat sink 100 may be mounted to a printed circuit board that the electronic device is also mounted to via attachment regions 108-110. Mounting of heat sink 100 to a printed circuit board is described in more detail with reference to FIGS. 2-5.

FIG. 2 is a perspective view of a heat sink 200 with load spreading bar, according to an example. Heat sink 200 may be similar to heat sink 100 of FIG. 1. Heat sink 200 may include load spreading bar 104 coupled to a main region 202. Main region 202 may include a set of cooling fins 204. Set of cooling fins 204 may include one or more cooling fin. A cooling fin may be a structure extending from a surface of main region 202 to increase the rate of heat transfer from main region 202 to the surrounding environment.

Main region 202 may also include a set of mounting holes, such as mounting holes 206-212. A mounting hole may be an opening to receive a fastener. For example, each of mounting holes 206-212 may receive a fastener, such as fasteners 214-220, respectively when heat sink 200 is mounted to a printed circuit board.

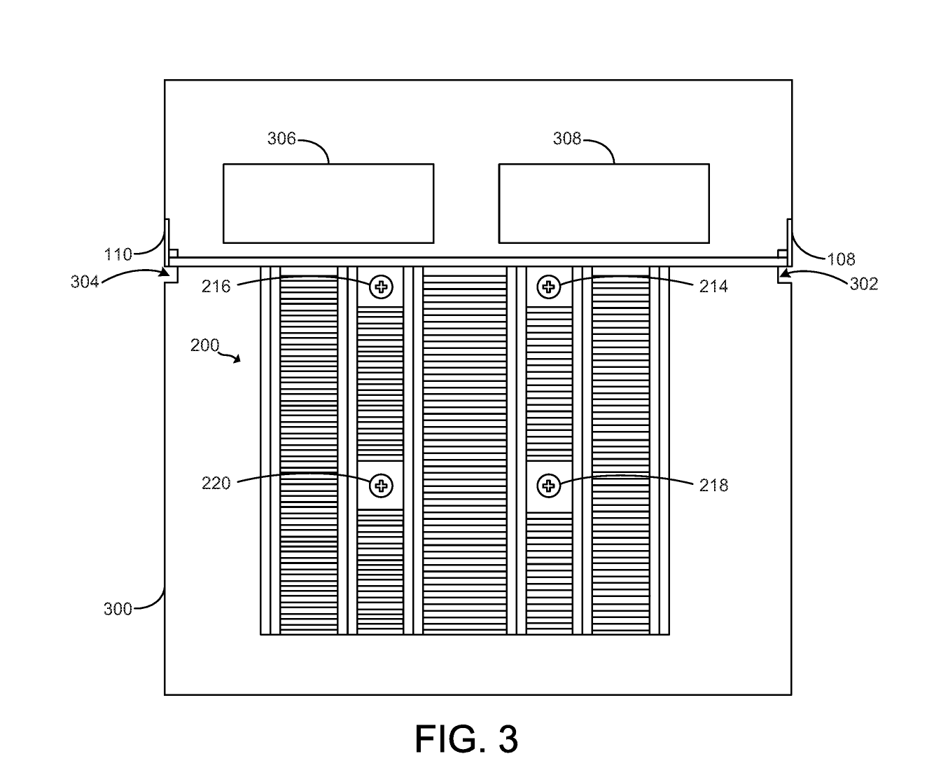

FIG. 3 is a top view of heat sink 200 with load spreading bar 104 mounted to a printed circuit board, according to an example. During operation, heat sink 200 may be mounted to a printed circuit board 300 via fasteners 214-220. Further, heat sink 200 may also be mounted to printed circuit board 300 via attachment regions 108-110. For example, first attachment region 108 may interface with a first notch 302 of printed circuit board 300 and second attachment region 110 may interface with a second notch 304 of printed circuit board 300. By utilizing attachment regions 108-110 to interface with notches 302-304, reallocations of components mounted on printed circuit board 300 may be avoided. For example, memory modules 306-308 may be mounted on printed circuit board 300 at a location that is in close proximity to heat sink 200. Reallocation of memory modules 306-308 may be avoided.

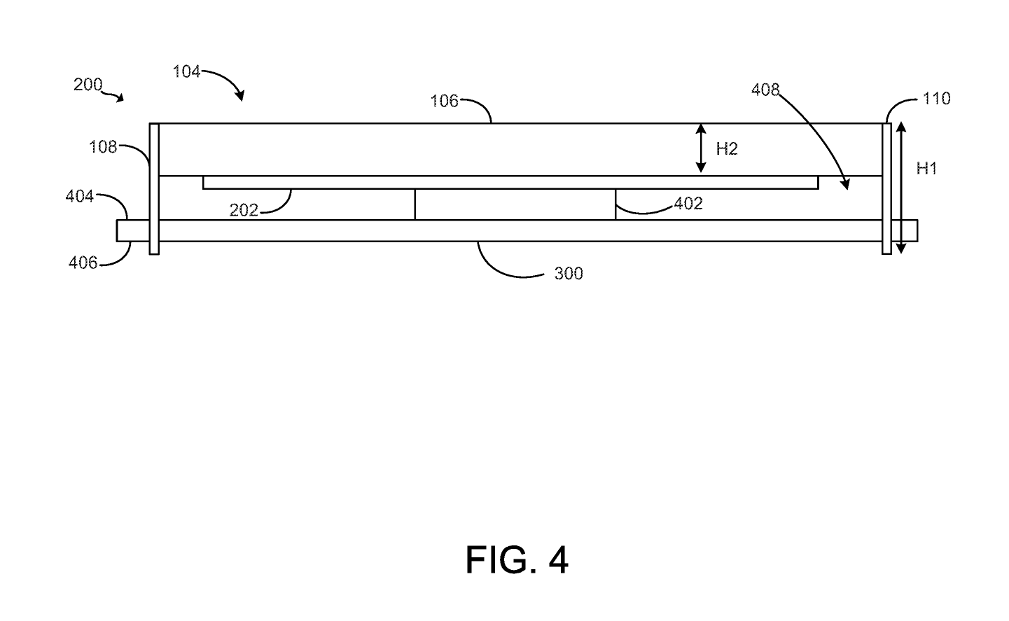

FIG. 4 is a side view of heat sink 200 with load spreading bar 104, according to an example. As illustrated in FIG. 4, when heat sink 200 is mounted to printed circuit board 300, main region 202 may interface with an electronic device 402 via physical contact. Electronic device 402 may be any electronic device that generates heat during operation, such as a processor. Attachment regions 108-110 may interface with both sides of printed circuit board, such as an upper side 404 and a lower side 406.

Attachment regions 108-110 may have the same height, such as a first height H1. Body region 106 may have a second height, H2, that is less than the first height H1. When mounted to printed circuit board 300, body region 106 may not be in physical contact with printed circuit board 300. Body region 106, first attachment region 108, and second attachment region 110 may define an opening 408 with respect to upper side 404 of printed circuit board 300. Thus, change to component layout on the region of printed circuit board 300 under body region 106 to accommodate body region 106 may be avoided. When printed circuit board 300 experiences any up and down motion, the up and down motion may be transfer to sides of printed circuit board 300 that interface with attachment regions 108-110 via load spreading bar 104. Thus, flexing experienced by the region of printed circuit board 300 where electronic device 402 is mounted to may be reduced.

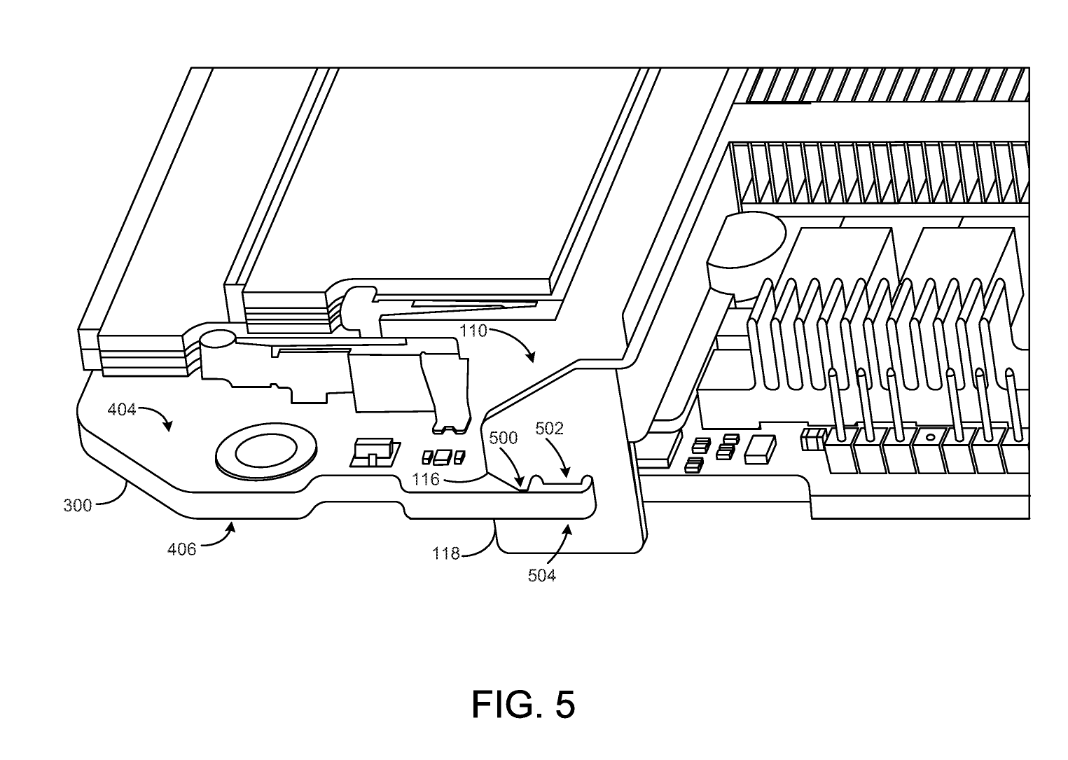

FIG. 5 is a respective view of second attachment region 110 of load spreading bar 104, according to an example. When mounted to printed circuit board 300, third attachment feature 116 may interface with upper side 404 via physical contact. Fourth attachment feature 118 may interface with lower side 406 via physical contact. In some examples, third attachment feature 116 may have a pointed region 500 and a flat region 502. Pointed region 500 may be in physical contact with upper side 404 and flat region 502 may not be in physical contact with upper side 404. In some examples, third attachment feature 116 may have a single flat region to interface with upper side 404. In some examples, fourth attachment feature 118 may have a rectangular shape so that a flat region 504 of fourth attachment feature 118 may be in physical contact with lower side 406. It should be understood that first attachment feature 112 may be similarly shaped as third attachment feature 116 and second attachment feature 114 may be similar shaped as fourth attachment feature 118.

According to the foregoing, examples disclosed herein provide a heat sink with a load spreading bar. For example, the heat sink may include a main region to interface with an electronic device. A load spreading bar may be coupled to the main region. The load spreading bar may include a first attachment region and a second attachment region to interface with an upper side and a lower side of a printed circuit board. Each attachment region may include at least one attachment feature, such as a tab, to interface with the printed circuit board. The load spreading bar may include a body region position between the first attachment region and the second attachment region. The body region may not be in physical contact with the printed circuit board when the heat sink is mounted to the printed circuit board. When the heat sink is mounted to the printed circuit board, an up and down motion experienced by the printed circuit board may be transferred to sides of the printed circuit board via the load spreading bar. Thus, a likelihood of damage to the printed circuit board due to structural flexing may he reduced.

The use of “comprising”, “including” or “having” are synonymous and variations thereof herein are meant to be inclusive or open-ended and do not exclude additional unrecited elements or method steps.

What is claimed is:

1. A heat sink comprising:
a main region to interface with an electronic device mounted to a printed circuit board, wherein the printed circuit board includes an upper side and a lower side; and
a load spreading bar coupled to the main region, wherein the load spreading bar includes:
a first attachment region including a first attachment feature and a second attachment feature, wherein the first attachment feature is to interface with the upper side, and wherein the second attachment feature is to interface with the lower side; and
a second attachment region to interface with the printed circuit board.

2. The heat sink of claim 1, wherein the second attachment region includes a third attachment feature and fourth attachment feature, wherein the third attachment feature is to interface with the upper side, and wherein the fourth attachment feature is to interface with the lower side.

3. The heat sink of claim 1, wherein a distance between the first attachment region and the second attachment region is greater than a width of the main region.

4. The heat sink of claim 1, wherein he load spreading bar includes a body region that is substantially straight.

5. The heat sink of claim 4, wherein the first attachment region has a first height, and wherein the body region has as second height that is less than the first height.

6. A heat sink comprising:
a main region to interface with an electronic device mounted to a printed circuit board, wherein the printed circuit board includes an upper side and a lower side, and wherein the main region includes:
a set of mounting holes; and
a set of cooling fins; and
a load spreading bar coupled to the main region, wherein the load spreading bar includes:
a first attachment region including a first attachment feature and a second attachment feature, wherein the first attachment feature is to interface with the upper side, and wherein the second attachment feature is to interface with the lower side; and
a second attachment region to interface with the printed circuit board.

7. The heat sink of claim 6, wherein the second attachment region includes a third attachment feature and fourth attachment feature, wherein the third attachment feature is to interface with the upper side, and wherein the fourth attachment feature is to interface with the lower side.

8. The heat sink of claim 6, wherein the first attachment feature corresponds to a first tab having a pointed region, and wherein the second attachment feature corresponds to a second tab that has a rectangular shape.

9. The heat sink of claim 6, wherein the load spreading bar includes a body region that is substantially straight.

10. The heat sink of claim 9, wherein the first attachment region has a first height with respect to the printed circuit board, and wherein the body region has as second height that is less than the first height.

11. A heat sink comprising:
a main region to interface with an electronic device mounted to a printed circuit board, wherein the printed circuit board includes an upper side and a lower side, and wherein the main region includes:
a set of mounting holes; and
a set of cooling fins; and
a load spreading bar coupled to the main region, wherein the load spreading bar includes:
a body region;
a first attachment region coupled to the body region, wherein the first attachment region includes a first attachment feature and a second attachment feature, wherein the first attachment feature is to interface with the upper side, and wherein the second attachment feature is to interface with the lower side; and
a second attachment region coupled to the body region, wherein the second attachment region is to interface with the printed circuit board, and wherein the body region, the first attachment region, and the second attachment region define an opening with respect to the printed circuit board.

12. The heat sink of claim 11, wherein the second attachment region includes a third attachment feature and fourth attachment feature, wherein the third attachment feature is to interface with the upper side, and wherein the fourth attachment feature is to interface with the lower side.

13. The heat sink of claim 11, wherein the first attachment feature corresponds to a first tab having a pointed region, and wherein the second attachment feature corresponds to a second tab that has a rectangular shape.

14. The heat sink of claim 11, wherein the body region is substantially straight.

15. The heat sink of claim 11, wherein the first attachment region has a first height, and wherein the body region has as second height that is less than the first height.
